(19) United States
(12) Patent Application Publication
(10) Pub. No.: US 2010/0052163 A1
(43) Pub. Date: Mar. 4, 2010

(54) SEMICONDUCTOR DEVICE, METHOD OF MANUFACTURING SAME AND METHOD OF REPAIRING SAME

(75) Inventor: Akira Ouchi, Minato-ku (JP)

Correspondence Address: SUGHRUE MION, PLLC, 2100 PENNSYLVANIA AVENUE, N.W., SUITE 800, WASHINGTON, DC, 20037, US

(73) Assignee: NEC CORPORATION, Minato-ku, Tokyo (JP)

(21) Appl. No.: 12/597,716

(22) PCT Filed: Apr. 25, 2008
(86) PCT No.: PCT/JP2008/058091

§ 371 Date: Oct. 26, 2009

(30) Foreign Application Priority Data
Apr. 27, 2007 (JP) 2007-118913

(51) Int. Cl. H01L 23/498; H01L 21/768

(52) U.S. Cl. 257/737; 438/613; 257/E23.068; 257/E21.589

(57) ABSTRACT

A semiconductor device in which opposing electrodes of a semiconductor component and of a wiring board are arranged to conduct via bumps, comprises: a first conductive resin bump provided on the electrode of the semiconductor component; and a second conductive resin bump provided on the electrode of the wiring board. The difference between a glass transition temperature of the first conductive resin bump and a glass transition temperature of the second conductive resin bump is equal to or greater than 40° C.

### REFERENCE TO RELATED APPLICATION

This application is based upon and claims the benefit of the priority of Japanese patent application No. 2007-118913 filed on Apr. 27, 2007, the disclosure of which is incorporated herein in its entirety by reference thereto.

### TECHNICAL FIELD

This invention relates to a semiconductor device of flip chip or chip scale package type using bumps of conductive resin, and methods of manufacturing and of repairing the same. More particularly, the invention relates to a semiconductor device, which is for obtaining excellent productivity while assuring reliable electrical connections and which is repairable after mounting, a method of manufacturing this device and a method of repairing the same.

### BACKGROUND ART

With the rapid development of electronic equipment, multiple functions surpassing those available so far are being sought for semiconductor devices. The greater functionality of semiconductor devices has been accompanied by an increase in the number of input/output pins of semiconductor devices, and a shortening of wiring length for operating semiconductor devices at high speed is being sought. A flip chip connection is available as a connection method developed in order to realize these demands. The flip chip connection is suited to an increase in number of pins since the wiring surface of a semiconductor device can be provided with connection pads because of the area available. Further, in comparison with other connection methods such as wire bonding and tape automated bonding, it is possible to shorten wiring length because the flip chip connection does not require leads. For these reasons, increasing use is being made of flip chip connections in the mounting of semiconductor devices employed in electronic equipment.

At present, Au and solder, etc., are being used as the general material the bumps employed in a flip chip. Although Sn—Pb eutectic solder is available as an example of solder material, the solder material is not limited to Sn—Pb eutectic solder. For example, materials that can be mentioned are Sn—Pb (with the exception of the crystal), Sn—Ag, Sn—CU, Sn—Sb, Sn—Zn and Sn—Bi, as well as materials obtained by adding a specific additional element to these materials. These materials are used as appropriate (Conventional Art 1).

In many flip-chip-connected semiconductor devices, it is necessary that connection reliability be assured by resin-sealing the gaps between semiconductor components and the wiring board in order to mitigate stress ascribable to a difference in thermal expansion between the semiconductor components and the wiring board. Such an example is disclosed in Patent Document 1. Used as the resin material employed in such a resin seal are epoxy resin, silicone resin, phenol resin, diallyl phthalate resin, polyimide resin, acrylic resin and urethane resin, etc. Among these, epoxy resin is widely used owing to its outstanding heat resistance, humidity resistance, chemical resistance, adhesion and cost, etc.

Further, a flip chip package in which conductive resin bumps exhibiting a low elastic modulus are used for the purpose of lowering stress after packaging has been proposed (Conventional Art 2). Such an example is disclosed in Patent Document 2.

[Patent Document 1] Japanese Patent Kokai Publication No. JP-A-11-233558

[Patent Document 2] Japanese Patent Kokai Publication No. JP-P2000-332053A

### DISCLOSURE OF THE INVENTION

### Problems to be Solved by the Invention

The particulars disclosed in the above-mentioned Patent Documents 1 and 2 are hereby incorporated by reference herein in their entirety. An analysis of the related art according to the present invention is given below.

In a case where a semiconductor component and a wiring board are connected using solder bumps, as in Conventional Art 1, a resin seal is implemented in order to mitigate stress ascribable to a difference in thermal expansion between the semiconductor component and the wiring board, thereby enhancing reliability of the connection between the semiconductor component and the wiring board. However, the elastic modulus of the solder bumps is much higher in comparison with that of the resin. For example, whereas the elastic modulus of Sn-3AG-0.5Cu solder is about 40 GPa, the elastic modulus of epoxy resin is on the order to 10 GPa even in a case where the elastic modulus is raised by mixing in a filler. This results in a stress distribution in which stress readily concentrates in the solder portions of high elastic modulus, thus resulting in high stress, while a low stress develops in the resin portions of low elastic modulus. In other words, the electrode portions that connect the semiconductor component and the wiring board develop a high stress as before, and in some cases there is the danger that this will lead to defects such as the occurrence of cracks in the solder bumps.

Accordingly, it is required that the elastic modulus of the resin portions be raised in order to improve the connection reliability of the solder bumps. A method of mixing an inorganic filler with a resin is available as the most common method of raising the elastic modulus of the resin portions. If too much inorganic filler is mixed with a resin, however, the viscosity of the resin rises abnormally. As a consequence, a problem which arises is that sufficient fluidity of the resin cannot be assured and the resin seal per se between the semiconductor component and wiring board is difficult to achieve. Hence there is a limitation upon the amount of inorganic filler that can be mixed in.

With the higher packing densities and greater performance of LSI (Large-Scale Integration), a weakening of the mechanical strength of the LSI interlayer insulating film is predicted owing to substitution of an insulating film referred to as so-called “low-k film” (low specific dielectric constant film) for the interlayer insulating film. With a structure in which an LSI chip using an interlayer insulating film comprising such a low-k film has been connected to a wiring board by a solder bump, a problem which arises is that if the solder bump is subjected to a high stress, the weakened interlayer insulating film will be destroyed even if the solder bump itself does not encounter any problem.

Further, if a semiconductor component and a wiring board are connected by a solder bump made of a material having a high elastic modulus, warpage increases and mountability of the semiconductor component declines as a matter of course. And owing to warpage behavior and concentration of stress owing to a change in temperature, there is the danger that the wiring board and the semiconductor component itself will crack.

Lowering the elastic modulus of the sealing resin is effective for dealing with warpage. If the elastic modulus of the sealing resin is lowered, however, the difference in elastic modulus between the solder bump and the sealing resin will become more pronounced. As a consequence, connection reliability declines and a problem which arises is that a guarantee of reliability between the semiconductor component and wiring board and a reduction in warpage cannot both be achieved.

In a case where a semiconductor component and a wiring board are connected using conductive resin bumps, as in Conventional Art 2, the use of the conductive resin bumps makes it possible to lower the elastic modulus of the bumps per se and therefore a stress-mitigating effect can be expected. In the case of a conductive resin bump, however, a melting point as in the case of a solder bump does not exist. This means that a conductive resin bump has two particular problems, one being that it is difficult to achieve both a guarantee of a stable connection and high productivity, and the other being that repair after packaging is difficult.

Specifically, in the case of conductive resin bumps, in order to accommodate variations in height at the time of bump formation and obtain a stable connection for all bumps, it is required that the conductive resin bumps be deformed by more than the amount of height variation thereof at the very least. A method of achieving this is to package the device by forming bumps of uncured conductive resin on the pad prior to packaging. In the case of this method, if hardened conductive resin bumps are formed on at least one side, namely the side of the semiconductor component or the side of the wiring board, and the gap between the semiconductor component and the wiring board is assured by the bumps, then the uncured conductive resin bumps can accommodate variations in bump height and all bumps can be connected. In this case, however, uncured conductive resin adheres strongly to a hardened conductive resin bump. And since no melting point exists as in the case of solder, if an attempt at repair is made after mounting, this may cause exfoliation of the board pads, rendering repair impossible.

An example of a repair measure that can be mentioned is to weaken the strength of the conductive resin bumps to thereby prevent pad destruction. However, even if this method allows a semiconductor component to be removed at the time of repair without destroying the pads, the way in which the conductive resin bumps remain on the board pad following removal of the semiconductor component will differ greatly from pad to pad and it will be necessary to level the bump heights in order to remount the semiconductor component. However, a problem which arises is destruction of the board pads or expenditure of considerable labor at the time of the operation for leveling bump height. The reason is that in the case of a conductive resin bump, a melting point such as that of a solder bump does not exist and the strength of adhesion between the board pad and the wiring board is weaker than that of another board surface, and this can promote exfoliation.

Specifically, as means for leveling the heights of conductive resin bumps exhibiting a variation in height, there is a method of collectively trimming conductive resin bumps of different heights so as to obtain a uniform height by using a spatula or the like. In the case of this method, however, high bumps are subjected to greater force and hence there are instances where this leads to pad destruction when this operation is performed.

A method of weakening the conductive resin to the maximum extent is available as a method of preventing pad damage. However, in a case where the conductive resin is weakened and it is attempted to assure connection reliability, the conductive bump attains a state in which it is readily deformed, as in the manner of rubber, it is difficult to trim the bumps as by using a spatula and the variations in height cannot be uniformalized in simple fashion. Further, if it is attempted to physically deform or weaken conductive resin, a problem which arises is that the conductive resin bumps tend to be destroyed by stress at the time of packaging and reliability declines even if repair can be achieved.

Further, available as a method of enabling repair by weakening the strength of the connection portion of a conductive resin bump is a method of connecting one conductive resin bump in a semi-hardened state rather than in an uncured state and lowering the strength of adhesion between bumps after the connection is made. In this case, however, if the hardening of the conductive resin bump is inadequate, adhesion strength cannot be reduced and, as before, the problem of an inability to make repairs is not improved upon. This means that it is necessary to allow the hardening of the conductive resin to proceed to a certain extent and weaken the strength of connection between bumps by a large margin. However, if the conductive resin bump on the side of the semiconductor component and the conductive resin bump on the side of the wiring board are made of the same resin, then the more hardening proceeds, the more the physical properties of the resin on the side of the semiconductor component and on the side of the wiring board approach each other. As a result, neither of the two conductive resin bumps are deformed at the time of mounting and a good state of conduction cannot be assured. Alternatively, both of the conductive resin bumps are deformed, a gap between the semiconductor component and the board can no longer be assured and, moreover, this can lead to a major problem in which mutually adjacent conductive resin bumps come into electrical contact and are shorted when they are deformed. Even in the case of a semi-hardened condition in which the connection strength between conductive resin bumps can be weakened and it is possible to cause deformation of only one of the conductive resin bumps, the fact that hardening proceeds means that retention in the semi-hardened condition requires bump formation immediately prior to mounting and implementation of stringent control over the hardening conditions. Hence there are major limitations at the time of production. Furthermore, with a conductive resin in which there is a strict limitation regarding hardening conditions, a problem which arises is that a decline in packageability and reparability is brought about by a variation in hardness at the time of production.

As mentioned above, a flip chip connection involves a structure suited to higher performance and an increase in demand for such a structure is foreseen for the future. However, in a case where use is made of solder bumps, assuring high reliability, lowering stress and reducing warpage, etc., remain as problems. In particular, in a case where an insulating film layer having weak mechanical strength is used in an LSI chip in the future, it is highly likely that it will not be possible to assure reliability, and lowering stress and reducing warpage will be particularly important. In addition, in a case where conductive resin bumps are used, assuring productivity and repairability is a problem.

It is a main object of the present invention to realize excellent productivity, high connection reliability, little warpage and low-stress packaging with regard to a semiconductor device of the flip chip and chip scale package type, and to make repair possible.

### Means to Solve the Problems

In a first aspect of the present invention, there is provided a semiconductor device in which opposing electrodes of a semiconductor component and of a wiring board are arranged to conduct via bumps, characterized by comprising: a first conductive resin bump provided on the electrode of the semiconductor component, and a second conductive resin bump provided on the electrode of the wiring board; wherein the difference between a glass transition temperature of the first conductive resin bump and a glass transition temperature of the second conductive resin bump is equal to or greater than 40° C.

In the semiconductor device of the present invention, it is preferred that a gap between the semiconductor component and the wiring board is sealed by an insulating resin. (Mode 1-1)

In a second aspect of the present invention, there is provided a method of manufacturing the semiconductor device, characterized by comprising: a step of forming a first conductive resin bump on an electrode of a semiconductor component; a step of forming a second conductive resin bump on an electrode of a wiring board; and a step of registering the semiconductor component and the wiring board in a state in which heating has been performed to a temperature between a glass transition temperature of the first conductive resin bump and a glass transition temperature of the second conductive resin bump.

The method of manufacturing the semiconductor device of the present invention preferably further comprises a step of applying an insulating resin to a mounting surface of the semiconductor component on the wiring board, this step being after the step of forming the second conductive resin bump and before the step of applying heat and pressure; and a step of hardening the insulating resin at or after execution of the step of applying heat and pressure. (Mode 2-1)

The method of manufacturing the semiconductor device of the present invention preferably further comprises a step of sealing and hardening an insulating resin between the semiconductor component and the wiring board after the step of applying heat and pressure. (Mode 2-2)

In a third aspect of the present invention, there is provided a method of repairing the semiconductor device, characterized by comprising a step of removing the semiconductor component from the wiring board after heating has been performed to a temperature between the glass transition temperature of the first conductive resin bump and the glass transition temperature of the second conductive resin bump. (Mode 2-3)

### MERITORIOUS EFFECTS OF THE INVENTION

In accordance with the first aspect of the present invention, in a process for packaging a semiconductor device, packaging is performed at a temperature near the glass transition temperature of the conductive resin bump having the higher glass transition temperature. As a result, even in a case where the hardening of both conductive resin bumps is proceeding, the elastic modulus of the conductive resin bump having the lower glass transition temperature will be a much lower elastic modulus and therefore only the conductive resin bump having the lower glass transition temperature is crushedly deformed selectively. Even if a load is applied, therefore, the gap between the semiconductor device and the wiring board is assured by the height of the conductive resin bump having the higher glass transition temperature. Further, since the conductive resin bump having the lower glass transition temperature is deformed following the shape of the conductive resin bump having the higher glass transition temperature, it is possible to maintain a broad contact area and a state that is suitable for assuring good conduction between the semiconductor device and the wiring board is attained. Further, conductive resin bumps are used on both the sides of the semiconductor device and wiring board. Since the elastic modulus is lower than that of metal bumps used generally in the conventional art, therefore, an effect obtained is mitigation of stress ascribable to a difference in coefficient of thermal expansion between the semiconductor device and wiring board. Assurance of high reliability, a reduction in stress and a reduction in warpage can thus be achieved. Furthermore, in a case where the semiconductor device is repaired, it is possible to perform removal selectively from the side of the conductive resin bumps having the lower glass transition temperature by making repair at a temperature near the glass transition temperature of the conductive resin bumps having the higher glass transition temperature. As a result, variations in residual height of the conductive resin bumps after removal of the semiconductor component can be uniformalized and repairability is improved remarkably.

In accordance with the mode (1-1) of the second [sic. first] aspect of the present invention, not only is the connection reliability of the conductive resin bump enhanced by sealing the conductive resin bump by the insulating resin but it is also possible to assure connection reliability owing to the protecting action and constricting force of the insulating resin even in a case where the connection strength between the conductive resin bumps is very weak. Repairability of the conductive resin bump is improved as a result. Further, in a case where a preliminary resin method of coating a wiring board with an insulating resin before the semiconductor device is mounted is applied as a mounting method using conductive resin bumps, the sealing resin and an unhardened conductive resin bump mix together and mounting cannot be achieved if hardening of the second conductive resin bump on the side of the wiring board does not proceed. In the case of the present structure, however, even if the conductive resin bump on the side on the semiconductor device and on the side of the wiring board have hardened sufficiently, a state of excellent conduction can be assured by selectively deforming only the conductive resin bump having the lower glass transition temperature. As a result, application of the preliminary resin method using conductive resin bumps becomes possible and a further improvement in productivity can be achieved.

In accordance with the second aspect of the present invention, it is possible to obtain a package structure in which an excellent state of connection is obtained by selectively deforming a conductive resin bump having the lower glass transition temperature, and which assures high reliability, lower stress and less warpage. Further, even in a case where a semiconductor component after packaging develops a problem and repair becomes necessary, a package structure in which it is possible to achieve selective removal from conductive resin bumps having a lower glass transition temperature can be obtained.

In accordance with the mode (2-1) of the second aspect of the present invention, a connection portion that relies upon a conductive resin bump can be protected by an insulating resin immediately after mounting. This not only improves connection yield after packaging but also makes it possible to obtain a high productivity by adjusting curing speed of the insulating resin. Furthermore, it is possible to obtain a package structure in which even if the interface of the first conductive resin bump on the side of the semiconductor component and the second conductive resin bump on the side of the wiring board is in a contacting state, connection reliability can be assured by adjusting the coefficient of thermal expansion of the insulating resin.

In accordance with another mode (2-2) of the present invention, a bump connection portion is protected by a resin seal after bump connection is achieved. This improves the connection reliability of the bump connection portion.

In accordance with another mode (2-3) of the present invention, even in a case where a semiconductor component after packaging develops a problem and repair becomes necessary, it is possible to selectively remove conductive resin bumps having a lower glass transition temperature and repairs can be made in excellent fashion.

### BRIEF DESCRIPTION OF THE DRAWINGS

FIG. 1 is a sectional view schematically illustrating the configuration of a semiconductor device according to a first exemplary embodiment of the present invention;

FIG. 2 is a sectional view schematically illustrating the configuration of a semiconductor device according to a second exemplary embodiment of the present invention;

FIG. 3 is a process sectional view schematically illustrating a method of manufacturing a semiconductor device according to a third exemplary embodiment of the present invention;

FIG. 4 is a process sectional view schematically illustrating a method of manufacturing a semiconductor device according to a fourth exemplary embodiment of the present invention;

FIG. 5 is a process sectional view schematically illustrating a method of repairing a semiconductor device according to a fifth exemplary embodiment of the present invention; and

FIG. 6 is a graph illustrating elastic moduli of a conductive resin A and a conductive resin B when temperature varies.

### EXPLANATION OF REFERENCE NUMBERS

1 semiconductor component
2 wiring board
3 first conductive resin bump (semiconductor-component side)
4 second conductive resin bump (wiring-board side)
5 pad (electrode on semiconductor-component side)
6 pad (electrode on wiring-board side)
7 insulating resin
8 spatula

### PREFERRED MODES FOR CARRYING OUT THE INVENTION

### First Exemplary Embodiment

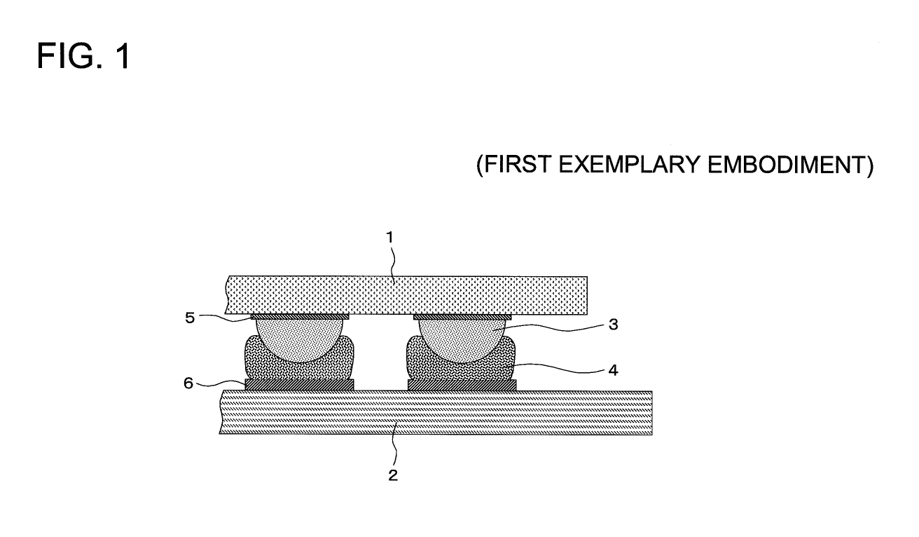

A semiconductor device according to a first exemplary embodiment of the present invention will be described with reference to the drawings. FIG. 1 is a sectional view schematically illustrating the configuration of a semiconductor device according to a first exemplary embodiment of the present invention.

In the semiconductor device of FIG. 1, a first conductive resin bump 3 is formed on a pad 5 of a semiconductor component 1, and a second conductive resin bump 4 is formed on a pad 6 of a wiring board 2. The second conductive resin bump 4 on the side of the wiring board 2 uses a conductive resin having a glass transition temperature that is lower than that of the first conductive resin bump 3 on the side of the semiconductor component 1 by 40° C. or more. Owing to a heating load applied when the semiconductor component 1 is mounted, the second conductive resin bump 4 on the side of the wiring board 2 is deformed along the shape of the surface of the first conductive resin bump 3 on the side of the semiconductor component 1. Since the first conductive resin bump 3 and second conductive resin bump 4 afford a broad contact area, it is possible to obtain stable conduction between the semiconductor component 1 and the wiring board 2.

It should be noted that when the second conductive resin bump 4 of lower glass transition temperature on the side of the wiring board 2 is deformed to follow the shape of the first conductive resin bump 3 of higher glass transition temperature on the side of the semiconductor component 1, the area of adhesion or contact between the bumps preferably is 50% or more of the area of the pad 5 of semiconductor component 1 or of the pad 6 of wiring board 2. The reason is that if the contact area is small, there is the danger that the joined portions will separate owing to deformation of the semiconductor component 1 or wiring board 2 ascribable to thermal stress, etc., at subsequent steps. Further, since the first conductive resin bump 3 on the side of the semiconductor component 1 is hardly deformed in comparison with the situation at the time of bump formation, a gap at least equivalent to the height of the first conductive resin bump 3 on the side of the semiconductor component 1 is maintained between the semiconductor component 1 and wiring board 2.

The semiconductor component 1 may be of any form, such as a chip scale package, ball grid array or bare chip, and there is no particular limitation as to its form. The semiconductor component 1 has a plurality of the pads 5 formed on the side thereof facing the wiring board 2.

The wiring board 2, which is a board obtained by forming wiring of copper of the like on an insulating material such as an organic resin or ceramic, may be of any form, such as a printed wiring board, multilayer wiring board or flexible wiring board, and there is no particular limitation as to its form. The wiring board 2 has a plurality of the pads 6 formed on the side thereof facing the semiconductor component 1.

The first conductive resin bump 3 is a ball-shaped terminal obtained by adding electrically conductive powder to an organic material. The first conductive resin bump 3 is formed on the pad 5 of semiconductor component 1.

Various resin materials can be used as the resin material of the first conductive resin bump 3, examples being acrylic resin, melamine resin, epoxy resin, polyolefin resin, polyurethane resin, polycarbonate resin, polystyrene resin, polyether resin, polyamide resin, polyimide resin, fluororesin, polyester resin, phenol resin, fluorene resin, benzocyclobutene resin and silicone resin. There is no particular limitation in this regard and one or two or more combinations of these resins can be used. Use of epoxy resin, which excels in terms of viscosity, cost and resistance to heat, is preferred. In view of productivity, it is preferred that the resin material of the first conductive resin bump 3 be a resin which, prior to hardening, is a liquid at a room temperature of 25° C., this being a condition for use of the resin.

The electrically conductive particles of the first conductive resin bump 3 are diverse. Use can be made of metal particles of copper, silver or nickel, etc., or of particles obtained by applying a conductive layer (e.g., metal plating of nickel or gold, etc.) to the surface of a core formed by a resin particle. By using conductive particles obtained by applying a conductive layer to the surface of a core formed by a resin particle, the physical properties of the conductive particles per se can be adjusted extensively. Furthermore, a better stress-reducing and warpage-reducing effect can be obtained since a reduction in elasticity can be achieved. The conductive particles of the first conductive resin bump 3 can take on a variety of shapes, such as that of a needle, sphere or flake, and there is no particular limitation. There are a variety of particle diameters of the conductive particles of the first conductive resin bump 3. The diameter can be made 10 μm, although there is no particular limitation. By mixing in metal nanoparticles as the conductive particles of the first conductive resin bump 3, the joining of conductive particles at the time of hardening of the resin material becomes possible owing to the melting-point lowering effect of the nanoparticles. This makes it easy to obtain a stable conduction characteristic.

In relation to the amount of the conductive particles added to the resin material in the first conductive resin bumps 3, this will differ depending upon particle shape, particle properties and method of manufacture, etc., and therefore it cannot be stipulated unconditionally. However, as one example that can be mentioned, it is preferred that the amount be equal to or greater than 30% and not more than 50% in a case where volume ratio is taken into consideration.

The second conductive resin bump 4 is a terminal obtained by adding conductive particles to a resin material. The second conductive resin bump 4 is formed on the pad 6 of wiring board 2. The resin material serving as the base material of the second conductive resin bump 4, the conductive particles, the particle shape, amount of particles added and the particle diameter, etc., may be similar to or different from those of the first conductive resin bump 3. However, it is necessary to so arrange it that the glass transition temperature of the second conductive resin bump 4 after the hardening thereof will be by 40° C. or more lower than that of the first conductive resin bump 3 after the hardening thereof.

There is no particular limitation with regard to a method of so arranging it that the glass transition temperature of the second conductive resin bump 4 after the hardening thereof will be by 40° C. or more lower than that of the first conductive resin bump 3 after the hardening thereof. However, taking as an example a case where both bumps use epoxy resin as the base material, this can be achieved by utilizing a difference in properties of curing agents, as by using an anhydride or an amino curing agent in the first conductive resin bump 3 having the higher glass transition temperature, maintaining the glass transition temperature at 130° C. or higher and using a phenol curing agent in the second conductive resin bump 4 having the lower glass transition temperature. Further, even in a case where the same curing agent is used, there are various methods which are available, such as changing the resin structure after hardening or adding a thermoplastic resin such as acryl to one of the curing agents. Further, different resins may be used as the resin per se, and this can be achieved by using an epoxy-resin-based conductive resin bump as the first conductive resin bump 3 having the higher glass transition temperature and using a silicone-resin-based conductive resin bump as the second conductive resin bump 4 having the lower glass transition temperature.

With regard to the state of the conductive resin bumps 3 and 4 when the semiconductor component 1 is mounted on the wiring board 2, it is preferred that the first conductive resin bump 3 of the higher glass transition temperature on the side of the semiconductor component 1 be hardened completely. This is to arrange it so that the first conductive resin bump 3 will not be formed when the semiconductor component 1 is packaged.

On the other hand, with regard to the state of the second conductive resin bump 4 of lower glass transition temperature on the side of the wiring board 2, two methods are available.

The first method is a method of hardening the second conductive resin bump 4 completely. In this case, the connecting portions of the first conductive resin bump 3 and second conductive resin bump 4 are both connected by the two completely hardened bumps and therefore the interface between the bumps is basically in a state of contact. However, by implementing packaging at a temperature between the glass transition temperature of the first conductive resin bump 3 and the glass transition temperature of the second conductive resin bump 4 or at a temperature in the vicinity of the glass transition temperature of the first conductive resin bump 3, only the second conductive resin bump 4 on the board side is selectively deformed, as illustrated in FIG. 1, thereby enabling contact over a wide area. In a case where the interface between the bumps is thus in a state of contact, repairability is excellent. However, it is necessary to use a continuously applied load or to produce a constricting stress while protecting the periphery by an insulating resin.

The second method is a method of adjusting hardness, which prevails immediately prior to mounting of the semiconductor component 1 of the second conductive resin bump 4 on the side of the wiring board 2, to a hardness indicative of the uncured or semi-cured state. Although packaging is possible by performing such an adjustment, it is possible to impart both bumps with adhesion depending upon the state of hardening of the second conductive resin bump 4 at this time. Hence, there are cases where a load during use and sealing using an insulating resin are unnecessary. In this case, however, owing to the adhesion of the two bumps, there is the danger that exfoliation of the pad 6 of wiring board 2 will occur when the semiconductor device is repaired. A measure for dealing with this is to make the glass transition temperature of the second conductive resin bump 4 on the side of the wiring board 2 much lower in comparison with the glass transition temperature of the wiring board 2. For example, performing repair at a temperature equal to or greater than the glass transition temperature of the second conductive resin bump 4 and lower than the glass transition temperature of the wiring board 2 is effective in preventing exfoliation of the pad 6 of wiring board 2.

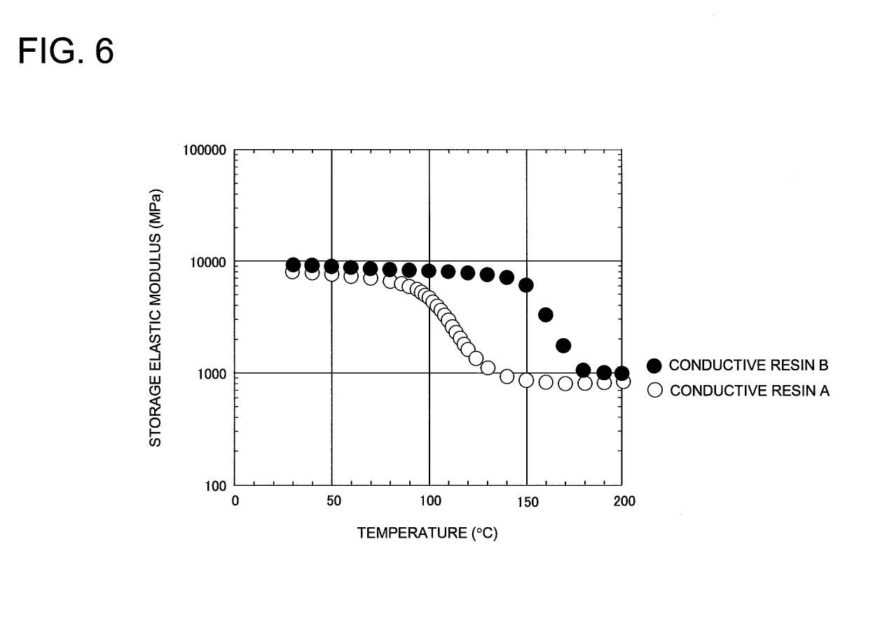

Discussed here is the reason why the difference between the glass transition temperature of the first conductive resin bump 3 and the glass transition temperature of the second conductive resin bump 4 is made by 40° C. or higher. FIG. 6 is a graph illustrating elastic moduli of a conductive resin A and a conductive resin B when temperature varies.

The conductive resin A has a glass transition temperature of 100° C. and the conductive resin B has a glass transition temperature of 138° C. The vertical axis of the graph of FIG. 6 indicates elastic modulus and the horizontal axis indicates temperature. The elastic modulus of the conductive resin A, which is on the order of 9 Gpa at room temperature, falls sharply from the vicinity of 100° C., which is the glass transition temperature, falls below 1 Gpa in the vicinity of 140° C. and stabilizes, with little change, at temperatures equal to or greater than this temperature. On the other hand, the elastic modulus of the conductive resin B falls sharply from the vicinity of 138° C., which is the glass transition temperature, falls to 1 Gpa in the vicinity of 180° C. and stabilizes, with little change, at temperatures equal to or greater than this temperature. In the case of these conductive resins, the range approximately of 120 to 150° C. affords a large difference in elastic modulus and is a packaging temperature condition suitable for obtaining a package structure that relies upon the first conductive resin bump 3 (which corresponds to the conductive resin B) and the second conductive resin bump 4 (which corresponds to the conductive resin A) of the first exemplary embodiment. In a case where a change in the elastic moduli of the two conductive resins A and B with respect to temperature is observed, it will be understood that the region where the decline in the elastic moduli for both resins starts from the vicinity of the glass transition temperature and the sharp decline in elastic moduli continues is a range of temperatures of about 40° C. In other words, in a case where an attempt is made to find a condition that will maximize the difference between the elastic moduli of the two conductive resins A and B, it will be understood that if the difference between the glass transition temperatures is equal to or greater than 40° C., such a difference in elastic modulus can be achieved in effective fashion.

It should be noted that the more the difference between the glass transition temperatures exceeds 40° C., the better, and that the difference can be made 50° C. or greater or 60° C. or greater, etc. However, the difference is selected in accordance with the materials used for the semiconductor component 1, wiring board 2, pad 5 and pad 6.

The pad 5 of the semiconductor component 1 can employ, e.g., copper or aluminum, etc., and it is also possible to use a pad obtained by forming nickel plating on the surface of such a metal and then further forming gold plating on the nickel plating. However, the invention is not limited to such an arrangement.

The pad 6 of the wiring board 2 can employ, e.g., copper, and it is also possible to use a pad obtained by forming nickel plating on the surface of the copper and then further forming gold plating on the nickel plating. However, the invention is not limited to such an arrangement.

In accordance with the first exemplary embodiment, a packaging method of connecting the electrodes of a semiconductor component and wiring board with the electrodes opposing each other as in the manner of a flip chip or CSP makes it possible to realize a package that excels in productivity, that enables low-warpage packaging ascribable to low-stress connections and that makes it possible to achieve both high connection reliability and repairability.

In the first exemplary embodiment, a case is described in which the second conductive resin bump 4 formed on the side of the wiring board 2 is deformed. However, implementation is possible by the same approach even in a case where the first conductive resin bump 3 on the side of the semiconductor component 1 is deformed by lowering its glass transition temperature.

### Second Exemplary Embodiment

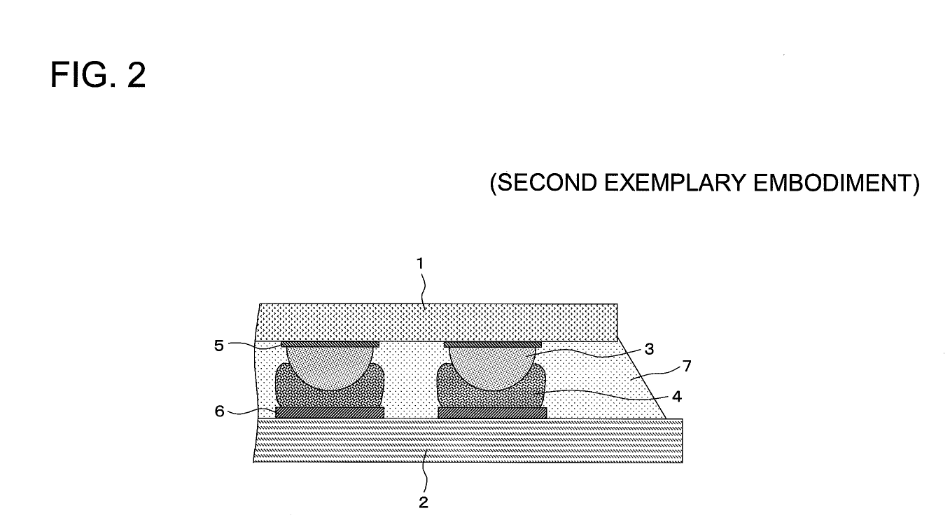

A semiconductor device according to a second exemplary embodiment of the present invention will be described with reference to the drawings. FIG. 2 is a sectional view schematically illustrating the configuration of a semiconductor device according to the second exemplary embodiment of the present invention.

The semiconductor device according to the second exemplary embodiment is such that the space between the semiconductor component 1 and wiring board 2 and the periphery of the bumps 3, 4 are sealed by an insulating resin 7. In other aspects, this exemplary embodiment is similar to the first exemplary embodiment.

It is preferred that the elastic modulus and glass transition temperature of the insulating resin 7 be similar to those of the second conductive resin bump 4 on the side of the wiring board 2. The reason is that when stress is produced in the second conductive resin bump 4 and insulating resin 7 owing to the difference between the coefficients of thermal expansion of the semiconductor component 1 and wiring board 2, the stress distribution can be uniformalized by making the elastic moduli of the second conductive resin bump 4 and insulating resin 7 approach each other, connection reliability can be improved, stress can be lowered and warpage reduced. In other words, in comparison with the metal bumps used generally in the conventional art, a case where conductive resin bumps are used makes it easier to bring the elastic moduli of the second conductive resin bump 4 and insulating resin 7 close together and affords major effects.

Further, since conductive particles of a metal filler, etc., have been added to the second conductive resin bump 4 in order to assure conductivity, mixing a prescribed amount of inorganic filler with the insulating resin 7 is effective as one example of a method of making the elastic modulus of the insulating resin 7 approach that of the second conductive resin bump 4 in this case. Although the type of inorganic filler is not particularly limited, spherical silica can be used. The average particle diameter of the inorganic filler is not particularly limited but can be made 2 to 3 μm.

Preferably, the coefficient of thermal expansion of the insulating resin 7 is made slightly larger than that of the second conductive resin bump 4. As one example of a guideline, for a second conductive resin bump 4 having a coefficient of thermal expansion of 20 to 30 ppm/° C. at a temperature below the glass transition temperature, the coefficient of thermal expansion of the insulating resin 7 would be, approximately, 35 to 70 ppm/° C. at a temperature below the glass transition temperature. The reason is as follows: By combining the coefficients of thermal expansion in the manner described, it is possible, owing to the constricting stress of the insulating resin 7, to apply a force in a direction that constantly presses the first conductive resin bump 3 on the side of the semiconductor component 1 and the second conductive resin bump 4 on the side of the wiring board 2 after packaging, thereby enabling an excellent state of conduction to be maintained between the bumps 3 and 4. Furthermore, it is possible to protect the connection interface and thereby assure reliability owing to the constricting stress of the insulating resin 7 even in a case where there is just contact at the entire interface of the first conductive resin bump 3 and second conductive resin bump 4. As a result, packaging can be achieved by completely hardening the second conductive resin bump 4 on the side of the wiring board 2 prior to packaging, and it is no longer necessary to take the trouble to perform bump formation immediately before packaging and to adjust the degree of hardness of the bump. This enhances productivity.

Further, assuming repair in a case where the semiconductor component 1 after packaging has developed a problem, preferably the strength of the connection between the first conductive resin bump 3 on the side of the semiconductor component 1 and the second conductive resin bump 4 on the side of the wiring board 2 is made weaker than the strength of adhesion between the semiconductor component 1 and pad 5 and between the wiring board 2 and pad 6, and the mechanical strength of the insulating resin 7 between the semiconductor component 1 and wiring board 2 is made lower than the mechanical strength of the wiring board 2.

The bump portion will be discussed first. In a case where the entire surface of the interface between the first conductive resin bump 3 on the side of the semiconductor component 1 and the second conductive resin bump 4 on the side of the wiring board is in a state of contact, the strength of the joint between the bumps 3 and 4 is very weak. Therefore, with regard also to the semiconductor component 1 and wiring board 2 having a very weak adhesion strength with respect to the pads, repair is possible without damaging the pad 5 of the semiconductor component 1 or the pad 6 of the wiring board 2.

Further, in a case where there is full or partial joining at the bump interface, if repair is made at a temperature intermediate the glass transition temperatures of the bump 4 and board 2 or at a temperature in the vicinity of the glass transition temperature of the wiring board 2 by making the glass transition temperature of the second conductive resin bump 4 on the side of the wiring board 2 lower than that of the wiring board 2, it is possible to lower the elastic modulus of the second conductive resin bump 4 on the side of the wiring board 2 to an extreme degree while the elastic modulus of the wiring board 2 is kept high. This enables repair without damaging the wiring board 2. By making the glass transition temperature of the first conductive resin bump 3 on the side of the semiconductor component 1 higher than that of the second conductive resin bump 4 on the side of the wiring board 2 at this time, it is possible to selectively remove the first conductive resin bump 3 from the second conductive resin bump 4. As a result, residual height of the second conductive resin bump 4 on the side of the wiring board 2 can be uniformalized and the subsequent repair operation can be performed efficiently.

The insulating resin portion will be discussed next. Here also, in a manner similar to that of the bump portions, the glass transition temperature of the insulating resin 7 is made lower than that of the wiring board 2 and repair is made at a temperature intermediate these two glass transition temperatures or at a temperature in the vicinity of the glass transition temperature of the wiring board 2, thereby making it possible to lower the elastic modulus of the insulating resin 7 by a wide margin in a state in which the wiring board 2 is sufficiently strong. As a result, it is possible to remove the insulating resin 7 and implement excellent repair without damaging the wiring board 2.

With regard to the assurance of connection reliability, a situation where the elastic modulus of the second conductive resin bump 4 and the elastic modulus of the insulating resin 7 are as near to each other as possible is best for uniformalizing the stress distribution, and this improves connection reliability, as mentioned earlier. Accordingly, if the elastic moduli of the second conductive resin bump 4 and insulating resin 7 are made to conform as much as possible and, moreover, the mechanical properties of the insulating resin 7 are made inferior to those of the wiring board 2 by adjusting the glass transition temperatures of the bump and resin, then it is possible to achieve both connection reliability and excellent repairability. The means for accomplishing this is to maintain the following relationship: “glass transition temperature of second conductive resin bump 4≈glass transition temperature of insulating resin 7<glass transition temperature of wiring board 2”.

In accordance with the second exemplary embodiment, effects similar to those of the first exemplary embodiment are obtained. It should be noted that the second exemplary embodiment has also been described with regard to a case where the second conductive resin bump 4 formed on the side of the wiring board 2 is deformed. However, implementation is possible by the same approach even in a case where the first conductive resin bump 3 on the side of the semiconductor component 1 is deformed by lowering its glass transition temperature.

### Third Exemplary Embodiment

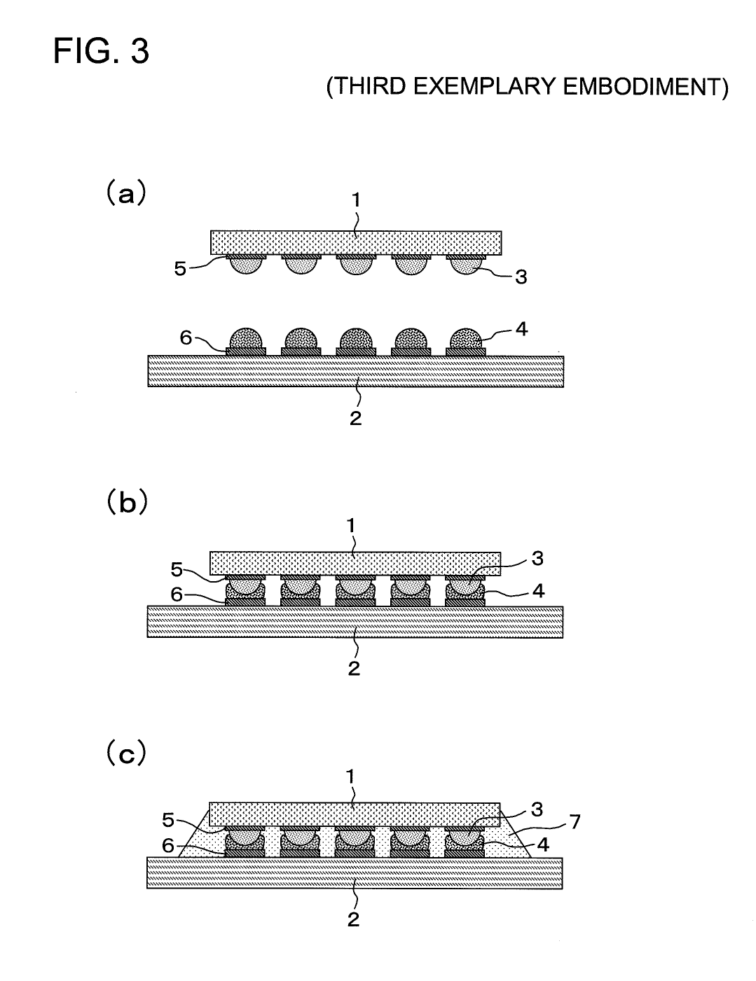

A method of manufacturing a semiconductor device according to a third exemplary embodiment of the present invention will be described. FIG. 3 is a process sectional view schematically illustrating a method of manufacturing a semiconductor device according to a third exemplary embodiment of the present invention.

First, the semiconductor component 1 and wiring board 2 are prepared, the first conductive resin bump 3 is formed on the pad 5 on the side of the semiconductor component 1 and the second conductive resin bump 4 is formed on the pad 6 on the side of the wiring board 2 [see (a) of FIG. 3]. At this time the first conductive resin bump 3 is allowed to harden completely and the second conductive resin bump 4 is left in the uncured or semi-hardened state.

Next, the semiconductor component 1 and wiring board 2 are registered, a heating load is applied to cause the second conductive resin bump 4 on the side of the wiring board 2 to follow the shape of the first conductive resin bump 3 on the side of the semiconductor component 1, and then the second conductive resin bump 4 is allowed to harden, thereby connecting the semiconductor component 1 and the wiring board 2 [see (b) of FIG. 3]. As a result, a semiconductor device similar to that of the first exemplary embodiment (see FIG. 1) is completed.

With regard to the heating and load conditions, it is required that these be made to conform to the characteristics of the resins used in the conductive resin bumps 3, 4. Although the conditions cannot be stipulated in a general fashion, the gap between the semiconductor component 1 and wiring board 2 can be kept at a fixed ratio and it is possible to obtain an excellent state of bump union by adopting conditions in which only the second conductive resin bump 4 is deformed with almost no deformation of the first conductive resin bump 3. An example of heating and load conditions that can be mentioned is the following profile: At the beginning of the joining of the bumps, the load is set high in order to positively deform the second conductive resin bump 4 on the side of the wiring board 2. With regard to heating, it is so arranged that only the second conductive resin bump 4 on the side of the wiring board 2 is deformed without deforming the first conductive resin bump 3 on the side of the semiconductor component 1 even though a load is applied. At the hardening step of the second conductive resin bump 4, heating is elevated in order to hasten hardening and the load is reduced in such a manner that the first conductive resin bump 3 on the side of the semiconductor component 1 will not be deformed. In a case where epoxy resin is used as the conductive resin bumps 3, 4, a guideline for the heating conditions is to adopt 100 to 150° C. as the heating temperature at the beginning of mounting and adopt 150 to 200° C. as the temperature for hardening of the second conductive resin bump 4 in the latter half of mounting. These conditions constitute an example suitable for raising productivity. If importance of low warpage and low stress is to be emphasized, then hardening should be allowed to continue at a temperature at 150° C. or below. The individual conditions thus change depending upon the objective. Therefore, although it is difficult to say as a general rule, what is important for obtaining an excellent connection is to eliminate warpage of the semiconductor component 1 and wiring board 2 as far as possible. If warpage is present, failure in the form of a non-connection tends to occur. As means for suppressing warpage, there is a method of strongly attracting the semiconductor component 1 and wiring board 2 at the time of packaging and a method of correcting warpage by applying a prescribed load at the time of mounting. If these measures are taken even during hardening of the second conductive resin bump 4, they will be effective in obtaining a stable connection.

Next, for the purpose of protecting the bump joint, after the semiconductor component 1 and wiring board 2 have been electrically connected, the gap between the semiconductor component 1 and wiring board 2 is filled with the insulating resin 7 utilizing capillarity and the insulating resin hardens [see (c) of FIG. 3]. As a result, a semiconductor device similar to that of the second exemplary embodiment (see FIG. 2) is completed.

### Fourth Exemplary Embodiment

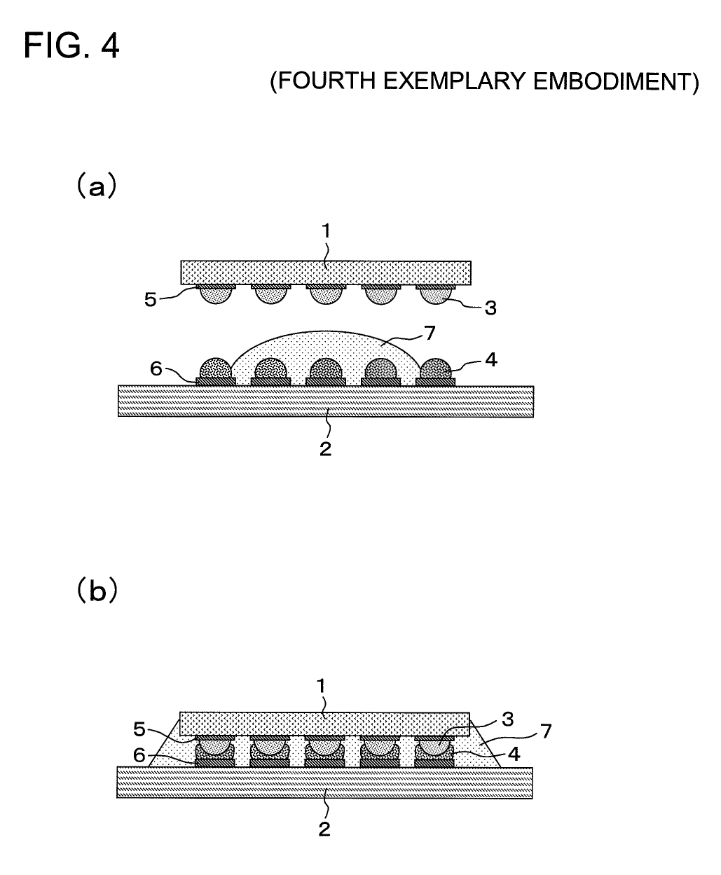

A method of manufacturing a semiconductor device according to a fourth exemplary embodiment of the present invention will be described with reference to the drawings. FIG. 4 is a process sectional view schematically illustrating a method of manufacturing a semiconductor device according to a fourth exemplary embodiment of the present invention.

First, in a manner similar to that of the third exemplary embodiment, the semiconductor component 1 and wiring board 2 are prepared, the first conductive resin bump 3 is formed on the pad 5 on the side of the semiconductor component 1 and the second conductive resin bump 4 is formed on the pad 6 on the side of the wiring board 2 [see (a) of FIG. 3]. At this time the first conductive resin bump 3 is allowed to harden completely and the second conductive resin bump 4 is left in the uncured or semi-hardened state.

Next, the location (near the center) on the wiring board 2 where the semiconductor component 1 will be mounted is coated with a prescribed amount of the insulating resin 7 (see (a) of FIG. 4].

Next, the semiconductor component 1 and wiring board 2 are registered, a heating load is applied to cause the second conductive resin bump 4 on the side of the wiring board 2 to follow the shape of the first conductive resin bump 3 on the side of the semiconductor component 1, and then the second conductive resin bump 4 and insulating resin 7 are allowed to harden while the heating load is kept applied, thereby connecting the semiconductor component 1 and the wiring board 2 [see (b) of FIG. 4]. As a result, a semiconductor device similar to that of the second exemplary embodiment (see FIG. 2) is completed.

Here the conductive connection between the first conductive resin bump 3 and second conductive resin bump 4 is maintained by the constricting stress of the insulating resin 7 after the hardening thereof. As a result, the second conductive resin bump 4 will have hardened completely prior to the mounting of the semiconductor component 1, and after packaging, it is possible to assure reliability even with nothing but contact at the interface of the first conductive resin bump 3. This means that it is possible to completely harden and fabricate the second conductive resin bumps 4 collectively beforehand. The result is excellent productivity. Furthermore, with this method, the conductive resin bumps 3, 4 are already protected by the insulating resin 7 at the time of removal of the load following the mounting of the semiconductor component 1. As a result, stress produced after mounting and initial yield are improved and excellent connection stability is achieved.

With regard to the heating and load conditions, it is required that these be made to conform to the characteristics of the resins used in the conductive resin bumps 3, 4 and insulating resin 7. Although the conditions cannot be stipulated without qualification, preferably it is so arranged that only the second conductive resin bump 4 on the side of the wiring board 2 is deformed with the first conductive resin bump 3 on the side of the semiconductor component 1 undergoing almost no deformation, and so that the insulating resin 7 is allowed to harden at an early stage. With regard to hardening of the insulating resin 7, that temperature and time will be decided while taking the resin hardening characteristics into account to enable the assurance of stable conduction is a precondition. It is preferred that the resin hardening characteristics be such that hardening will be achieved in a short period of time at a temperature not more than 200° C. With regard to load, this can be decided depending upon the elastic modulus, degree of hardening and number of bumps, etc., of the second conductive resin bump 4 on the side of the wiring board 2.

### Fifth Exemplary Embodiment

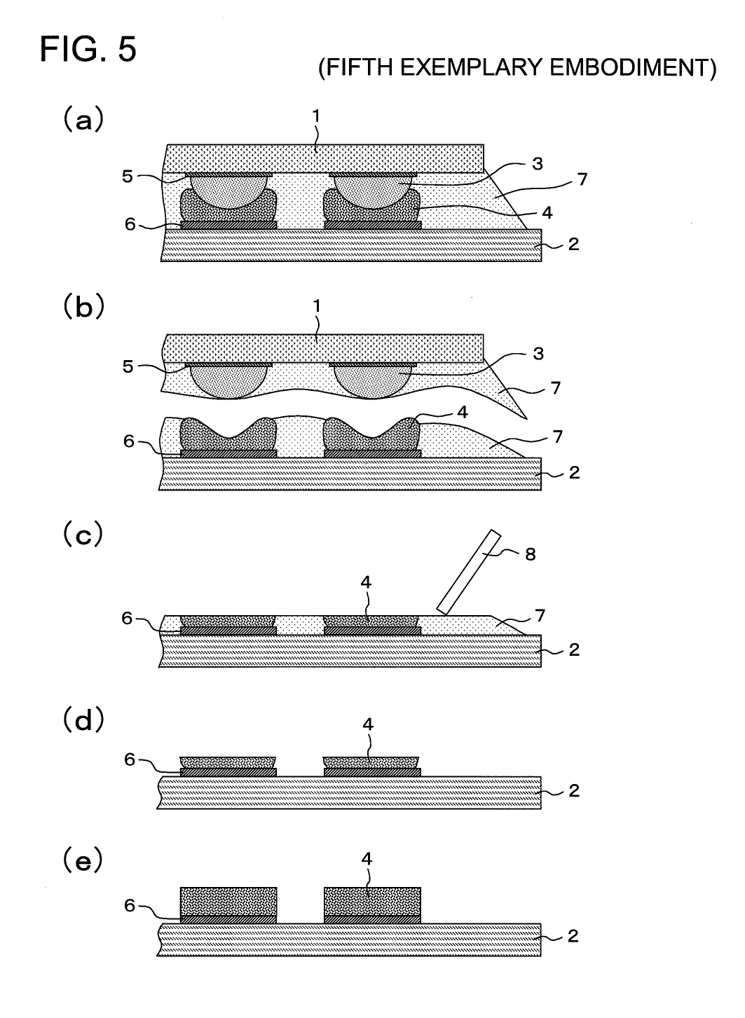

A method of repairing a semiconductor device according to a fifth exemplary embodiment of the present invention will be described with reference to the drawings. FIG. 5 is a process sectional view schematically illustrating a method of repairing a semiconductor device according to a fifth exemplary embodiment of the present invention.

First, a semiconductor device prior to repair in which the insulating resin 7 has been sealed is prepared and, in order to remove the semiconductor component 1 from the wiring board 2, the adhesion strength of the second conductive resin bump 4 and the mechanical strength of the insulating resin 7 are made sufficiently lower than the mechanical strength of the wiring board 2 and pad 6 [see (a) of FIG. 5]. One example of a method of making the adhesion strength of the second conductive resin bump 4 and the mechanical strength of the insulating resin 7 sufficiently lower than the mechanical strength of the wiring board 2 and pad 6 is to adopt the following heating requirements at the time of repair: establish a temperature higher than at least the glass transition temperatures of the second conductive resin bump 4 on the side of the wiring board 2 and the insulating resin 7, and make the temperature a temperature that is in the vicinity of the glass transition temperature of the wiring board 2.

Next, in the state in which the temperature has been made higher than the glass transition temperatures of the second conductive resin bump 4 on the side of the wiring board 2 and the insulating resin 7 and has been made a temperature in the vicinity of the glass transition temperature of the wiring board 2, the semiconductor component 1 is removed from the wiring board 2 [see (b) of FIG. 5]. A method of removing the semiconductor component 1 from the wiring board 2 is to insert a thin object of suitable rigidity, such as tweezers or a spatula, into the gap between the semiconductor component 1 and wiring board 2 and then lift up, thereby making removal possible. Another method is to affix a jig (not shown) to the underside of the semiconductor component 1 and then lift up the jig to thereby enable removal of the semiconductor component 1.

The insulating resin 7 and some of the second conductive resin remaining on the surface of the wiring board 2 are removed as by a spatula 8 [see (c) of FIG. 5]. The temperature at this time basically may be the temperature that prevailed when the semiconductor component 1 was removed. However, the temperature may be changed taking workability, etc., into consideration. Further, by cleansing the surface of the wiring board 2 using a solvent or the like at the finishing stage of removal of resin residue from the surface of the wiring board 2, it is possible to effectively remove the slight residue of the insulating resin 7 still adhering. The state attained by removal of the insulating resin 7 from the surface of the wiring board 2 is illustrated in (d) of FIG. 5.

Next, the second conductive resin bump 4 is formed again on the pad 6 on the side of the wiring board 2 [see (e) of FIG. 5]. This makes it possible to re-mount the semiconductor component 1. With regard to the re-formation of the second conductive resin bump 4, a printing method using a metal mask or the like can be used. In the case of this method, the amount of resin that was removed at the time of repair is supplied for each of the second conductive resin bumps 4. This is effective in terms of leveling bump height after repair.

It should be noted that it is possible to perform repair by the same method also with regard to repair in the case of a structure devoid of the insulating resin 7. In this case, it will suffice to merely re-form the second conductive resin bump 4 since the insulating resin 7 is absent. With regard to re-mounting of the semiconductor component 1, the methods described in the third and fourth exemplary embodiments can be applied.

Within the bounds of the entire disclosure of the present invention (inclusive of the claims), it is possible to modify and adjust the modes and exemplary embodiments of the invention based upon the fundamental technical idea of the invention. Multifarious combinations and selections of the various disclosed elements are possible within the bounds of the scope of the claims of the present invention.

1. A semiconductor device in which opposing electrodes of a semiconductor component and of a wiring board are arranged to conduct via bumps, comprising:
a first conductive resin bump provided on the electrode of said semiconductor component; and
a second conductive resin bump provided on the electrode of said wiring board;
wherein the difference between a glass transition temperature of said first conductive resin bump and a glass transition temperature of said second conductive resin bump is equal to or greater than 40° C.

2. The semiconductor device according to claim 1, wherein a gap between said semiconductor component and said wiring board is sealed by an insulating resin.

3. A method of manufacturing a semiconductor device comprising:
forming a first conductive resin bump on an electrode of a semiconductor component;
forming a second conductive resin bump on an electrode of a wiring board; and
registering said semiconductor component and said wiring board and applying heat and pressure in a state in which heating has been performed to a temperature between a glass transition temperature of said first conductive resin bump and a glass transition temperature of said second conductive resin bump.

4. A method of manufacturing a semiconductor device according to claim 3, further comprising:
applying an insulating resin to a mounting surface of said semiconductor component on said wiring board, after said forming said second conductive resin bump and before said applying heat and pressure; and
hardening said insulating resin at or after execution of said applying heat and pressure.

5. A method of manufacturing a semiconductor device according to claim 3, further comprising sealing and hardening an insulating resin between said semiconductor component and said wiring board after said applying heat and pressure.

6. A method of repairing a semiconductor device in which opposing electrodes of a semiconductor component and of a wiring board are arranged to conduct via bumps, comprising: a first conductive resin bump provided on the electrode of said semiconductor component; and a second conductive resin bump provided on the electrode of said wiring board; wherein the difference between a glass transition temperature of said first conductive resin bump and a glass transition temperature of said second conductive resin bump is equal to or greater than 40° C.,
the method comprising removing said semiconductor component from said wiring board after heating has been performed to a temperature between the glass transition temperature of said first conductive resin bump and the glass transition temperature of said second conductive resin bump.
